(19) United States
(12) Patent Application Publication
(10) Pub. No.: US 2023/0089623 A1
(43) Pub. Date: Mar. 23, 2023

(54) MOTION SENSOR ROBUSTNESS UTILIZING A ROOM-TEMPERATURE-VOLCANIZING MATERIAL VIA A SOLDER RESIST DAM

(71) Applicant: INVENSENSE, INC., San Jose, CA (US)

(72) Inventors: Efren Lacap, San Jose, CA (US); Milena Vujosevic, San Jose, CA (US)

(21) Appl. No.: 17/737,582

(22) Filed: May 5, 2022

Related U.S. Application Data
(60) Provisional application No. 63/247,430, filed on Sep. 23, 2021.

(51) Int. Cl. H01L 23/498; H01L 23/36

(52) U.S. Cl. CPC H01L 23/49805; H01L 23/36; H01L 23/49822

(57) ABSTRACT

Improving motion sensor robustness utilizing a room-temperature-volcanizing (RTV) material via a solder resist dam is presented herein. A sensor package comprises: a first semiconductor die; a second semiconductor die that is attached to the first semiconductor die to form a monolithic die; and a substrate comprising a top portion and a bottom portion, in which the top portion comprises a plurality of solder resist dams, the monolithic die is attached to the top portion of the substrate via the RTV material being disposed in a defined area of the top portion of the substrate, and the bottom portion of the substrate comprises electrical terminals that facilitate attachment and electrical coupling of signals of the sensor package to a printed circuit board.

### CROSS-REFERENCE TO RELATED APPLICATION

This patent application claims priority to U.S. Provisional Patent Application No. 63/247,430, filed on Sep. 23, 2021, and entitled “A NOVEL APPROACH TO IMPROVING CONSUMER MOTION SENSOR PRODUCT'S ROBUSTNESS IN HAND-HELD DEVICES,” the entirety of which is hereby incorporated by reference herein.

### TECHNICAL FIELD

This disclosure generally relates to embodiments for improving motion sensor robustness utilizing a room-temperature-volcanizing (RTV) material via a solder resist dam.

### BACKGROUND

Conventional semiconductor technologies utilize a die attach film (DAF) to connect a semiconductor die and/or chip to a substrate, circuit board, or other die during manufacture of a corresponding motion sensor device. However, the DAF directly transfers, to the semiconductor die, mechanical stress that has been applied, e.g., via temperature and/or force, to the motion sensor device. Consequently, conventional semiconductor technologies have had some drawbacks, some of which may be noted with reference to the various embodiments described herein.

### BRIEF DESCRIPTION OF THE DRAWINGS

Non-limiting embodiments of the subject disclosure are described with reference to the following figures, wherein like reference numerals refer to like parts throughout the various views unless otherwise specified:

FIG. 1 illustrates a diagram of a cross section of a sensor package in which an RTV material has been used, via solder resist dams, to facilitate improvement of a performance of the sensor package, in accordance with various example embodiments;

FIG. 2 illustrates a diagram of a cross section of a sensor package in which an RTV material has been placed on a monolithic die comprising a group of dies to facilitate improvement of a performance of the sensor package, in accordance with various example embodiments;

FIG. 3 illustrates a diagram of a cross section of a sensor package in which an RTV material has been used to secure a die to a monolithic die comprising a pair of dies to facilitate improvement of a performance of the sensor package, in accordance with various example embodiments;

FIG. 4 illustrates a diagram of top views of substrates comprising, respectively, a pair of solder resist dams that are arranged in a two-column pattern and a plurality of solder resist dams that are arranged in a rectangular pattern, in accordance with various example embodiments;

FIG. 5 illustrates a diagram of a top view of a substrate comprising a pair of solder resist dams that are arranged in a two-column pattern and RTV dispensed between the pair of solder resist dams to facilitate attachment of a sensor package between the pair of solder resist dams, in accordance with various example embodiments;

FIG. 6 illustrates a diagram of a top view of a substrate comprising a micro-electromechanical system (MEMS)-based microphone and a pair of solder resist dams that are arranged in a two-column pattern and RTV dispensed between the pair of solder resist dams to facilitate attachment of a die between the pair of solder resist dams, in accordance with various example embodiments;

FIG. 7 illustrates a diagram of a cross section of a sensor package in which an RTV material has been used to secure respective dies to a substrate to facilitate improvement of a performance of the sensor package, in accordance with various example embodiments; and

FIG. 8 illustrates a method of manufacturing a sensor package comprising disposing an RTV material on a defined area of a top portion of a substrate corresponding to a plurality of solder resist dams, in which a monolithic die is attached to the defined area during a defined viscous state of the RTV material, in accordance with various example embodiments.

### DETAILED DESCRIPTION

Aspects of the subject disclosure will now be described more fully hereinafter with reference to the accompanying drawings in which example embodiments are shown. In the following description, for purposes of explanation, numerous specific details are set forth in order to provide a thorough understanding of the various embodiments. However, the subject disclosure may be embodied in many different forms and should not be construed as limited to the example embodiments set forth herein.

As described above, mechanical stress that is applied to a sensor package is directly transferred to a die that has been attached, via a DAF, to a substrate, die, and/or circuit board of the sensor package—resulting in reduced sensor performance. Various embodiments disclosed herein can facilitate improvement of sensor performance of a device by attaching a sensor-based die to a substrate of the device utilizing an RTV material—the RTV material comprising a defined elasticity that facilitates absorption and/or isolation of external stress, e.g., caused by external temperature(s) and/or external force(s), that has been applied to the device.

For example, in embodiment(s), a sensor package, e.g., comprising a motion sensor, a MEMS-based sensor, a MEMS microphone, a MEMS accelerometer, or a MEMS gyroscope, comprises a first semiconductor die; a second semiconductor die that is attached to the first semiconductor die to form a monolithic die (e.g., the monolithic die comprising the motion sensor); and a substrate (e.g., comprising a laminate, a core insulating material, a glass-based material, or similar non-conductive material) comprising a top portion and a bottom portion.

The top portion of the substrate comprises a plurality of solder resist, or solder mask, dams, and the monolithic die is attached to the top portion of the substrate via an RTV material that is disposed in a defined area of the top portion of the substrate corresponding to the plurality of solder resist, or solder mask, dams. In this regard, in various embodiment(s), a boundary of the defined area comprises the plurality of solder resist, or solder mask, dams. Further, the bottom portion of the substrate comprises electrical terminals that facilitate attachment and electrical coupling of signals of the sensor package, e.g., to a printed circuit board (PCB).

In embodiment(s), the RTV material is disposed in the defined area of the top portion of the substrate during a defined viscous state of the RTV material—the defined viscous state representing a defined viscosity of the RTV material, e.g., during which the RTV material maintains a defined sticky, tacky, glutinous, or similar consistency; and the defined viscous state being between a defined solid state of the RTV material and a liquid state of the RTV material.

In this regard, in various embodiment(s), the plurality of solder resist dams prevents the RTV material from flowing, during the defined viscous state, beyond the plurality of solder resist dams.

In other embodiment(s), the RTV material is cured, after the monolithic die has been attached to the defined area during the defined viscous state, based on a defined applied heat that has been applied to the sensor package, and based on a defined applied temperature that has been applied to the sensor package, to obtain the defined solid state of the RTV material—the defined solid state of the RTV material comprising a defined elasticity, e.g., that facilitates absorption and/or isolation of an external stress, e.g., caused by external temperature(s) and/or external force(s), that has been applied to the sensor package.

In yet other embodiment(s), the RTV material is cured, after the monolithic die has been attached to the defined area, based on a desired bond line thickness of the RTV material.

In embodiment(s), the RTV material comprises a glass transition temperature that is equal to or less than negative 110 degrees Centigrade.

In other embodiment(s), the first semiconductor die or the second semiconductor die comprises redistribution layer circuitry or complementary metal-oxide-semiconductor (CMOS) circuitry.

In yet other embodiment(s), the first semiconductor die or the second semiconductor die comprises a MEMS device, e.g., microphone, accelerometer, gyroscope.

In embodiment(s), the sensor package further comprises a third semiconductor die that is attached to the monolithic die, or that is disposed on the top portion of the substrate.

In other embodiment(s), the plurality of solder resist dams comprises a pair of solder resist dams that are arranged in a two-column pattern, and the monolithic die is attached between the pair of solder resist dams.

In yet other embodiment(s), the plurality of solder resist dams is arranged in a rectangular pattern, and the monolithic die is attached within the rectangular pattern.

In embodiment(s), the plurality of solder resist dams comprises a defined height from the top portion of the substrate.

In other embodiment(s), a robustness of the sensor package, e.g., with respect to being subject to the external stress that has been applied to the sensor package, corresponds to a tumble test of a device comprising the sensor package, e.g., in which the device has been subject to repetitive random free-falls in a controlled manner, and/or a drop test of the device, e.g., in which the device has been dropped on its back, corner, and from 1 meter.

In yet other embodiment(s), an operating temperature range of the sensor package for which the tumble test and the drop test are performed is greater than or equal to −40 degrees Centigrade and less than or equal to 85 degrees Centigrade.

In embodiment(s), the sensor package further comprises a mold compound, e.g., comprising a plastic material, which is formed over the monolithic die, e.g., encapsulating the monolithic die.

In other embodiment(s), a method, e.g., of manufacture, of a sensor package comprises forming a first semiconductor die; forming a second semiconductor die; attaching the first semiconductor die to the second semiconductor die to form a monolithic die; and forming a substrate comprising a top portion and a bottom portion, in which the top portion comprises a plurality of solder resist dams, and in which the bottom portion comprises electrical terminals that facilitate attachment and electrical coupling of signals of the sensor package to a PCB.

The method further comprises: disposing, during a defined viscous state of an RTV material, the RTV material on a defined area of the top portion of the substrate corresponding to the plurality of solder resist dams, in which the defined area is located between the plurality of solder resist dams; attaching, during the defined viscous state of the RTV material, the monolithic die to the defined area corresponding to the plurality of solder resist dams; and based on a defined applied heat and a defined applied temperature, curing the RTV material to obtain a defined solid state of the RTV material comprising a defined elasticity.

In embodiment(s), the forming of the substrate further comprises forming the solder resist dams in a 2-column pattern, in which the solder resist dams are formed across from each other.

In other embodiment(s), the forming of the substrate further comprises forming the solder resist dams in a rectangular pattern.

In yet other embodiment(s), the curing of the RTV material comprises curing the RTV material based on a desired bond line thickness of the RTV material.

In embodiment(s), a sensor package, e.g., comprising a motion sensor, a MEMS-based sensor, a MEMS microphone, a MEMS accelerometer, or a MEMS gyroscope, comprises: a substrate comprising a top portion and a bottom portion, in which the top portion comprises a plurality of solder resist dams and at least one bond pad opening; a first semiconductor die that is attached to the substrate via an RTV material; and a second semiconductor die that is attached to the substrate via the RTV material, in which the bottom portion comprises electrical terminals that facilitate attachment and electrical coupling of signals of the sensor package to a PCB, and in which the plurality of solder resist dams prevent the RTV from contacting the bond pad opening(s).

In other embodiment(s), the substrate comprises through hole(s).

In yet other embodiment(s), the second semiconductor die is dispose over the through hole(s).

In embodiment(s), the sensor package further comprises a lid that is attached to the substrate.

Reference throughout this specification to “one embodiment,” or “an embodiment,” means that a particular feature, structure, or characteristic described in connection with the embodiment is included in at least one embodiment. Thus, the appearances of the phrase “in one embodiment,” or “in an embodiment,” in various places throughout this specification are not necessarily all referring to the same embodiment. Furthermore, the particular features, structures, or characteristics may be combined in any suitable manner in one or more embodiments.

Furthermore, to the extent that the terms “includes,” “has,” “contains,” and other similar words are used in either the detailed description or the appended claims, such terms are intended to be inclusive—in a manner similar to the term “comprising” as an open transition word—without precluding any additional or other elements. Moreover, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Furthermore, the word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art.

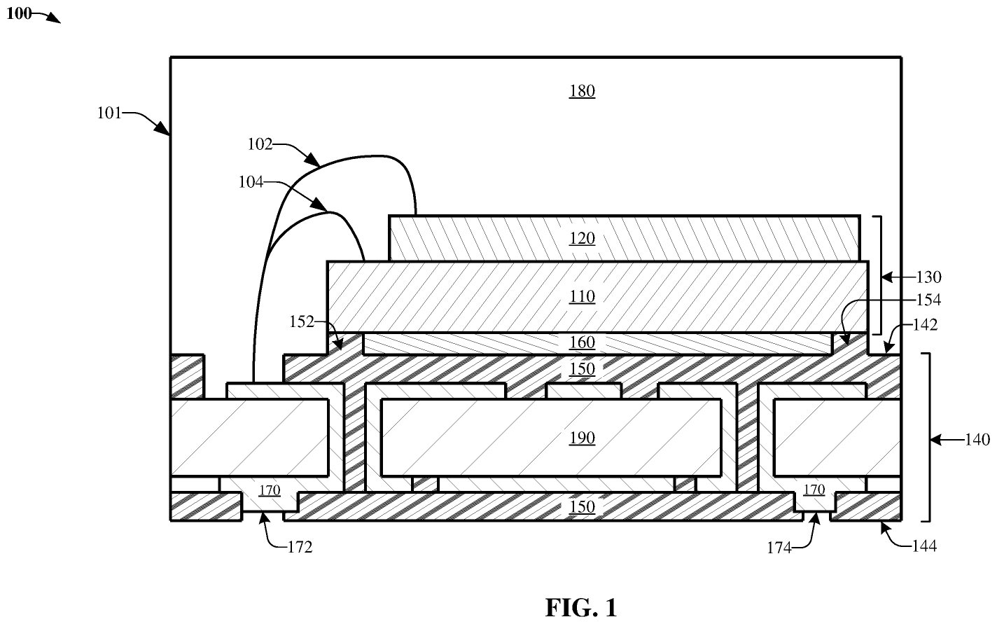

Referring now to FIG. 1, a diagram (100) of a cross section of a sensor package (101) in which an RTV material (160) has been used, via solder resist dams (152, 154), to facilitate improvement of a performance of the sensor package is illustrated, in accordance with various example embodiments. The sensor package comprises a motion sensor, e.g., a MEMS-based sensor/device (not shown), e.g., a MEMS microphone, a MEMS accelerometer, or a MEMS gyroscope, which is included in a first semiconductor die (110) or a second semiconductor die (120). The second semiconductor die is attached to the first semiconductor die to form a monolithic die (130), and in various embodiment(s), the first semiconductor die or the second semiconductor die comprises redistribution layer circuitry or complementary metal-oxide-semiconductor (CMOS) circuitry.

A substrate (140), e.g., comprising a laminate, a core insulating material, a glass-based material, or similar non-conductive material (190), comprises a top portion (142) and a bottom portion (144). The top portion of the substrate comprises a plurality of solder resist dams (152, 154) comprising a solder resist/solder mask material (150), and the bottom portion of the substrate comprises electrical terminals (172, 174) (e.g., comprising copper (170) that facilitate attachment and electrical coupling, via wires (102, 104), of signals of the sensor package corresponding to the motion sensor to a PCB (not shown).

In embodiment(s), the solder resist dams comprise a defined width, or a defined length, of at least 100 micrometers. In other embodiment(s), the solder resist dams comprise a defined thickness of less than or equal to 20 micrometers. In yet other embodiment(s), the solder resist dams comprise a defined height from the top portion of the substrate, e.g., comprising a layer of solder resist/solder mask, of 25+/−10 microns.

The monolithic die is attached to the top portion of the substrate via the RTV material, e.g., the RTV material being disposed within a boundary of a defined area of the top portion of the substrate during a defined viscous state of the RTV material, e.g., the boundary comprising the plurality of solder resist dams, e.g., the defined area located between the plurality of solder resist dams.

In embodiment(s), the defined viscous state represents a defined viscosity of the RTV material, e.g., during which the RTV material maintains a defined sticky, tacky, glutinous, or similar consistency; and the defined viscous state being between a defined solid state of the RTV material and a liquid state of the RTV material.

In this regard, in various embodiment(s), the plurality of solder resist dams prevents the RTV material from flowing, during the defined viscous state, beyond the plurality of solder resist dams.

In embodiment(s), the RTV material is cured, after the monolithic die has been attached to the defined area during the defined viscous state, based on a defined applied heat that has been applied to the sensor package, and based on a defined applied temperature that has been applied to the sensor package, to obtain the defined solid state of the RTV material—the defined solid state of the RTV material comprising a defined elasticity, e.g., that facilitates absorption and/or isolation of an external stress, e.g., caused by external temperature(s) and/or external force(s), that has been applied to the sensor package.

In other embodiment(s), a robustness of the sensor package, e.g., with respect to being subject to the external stress that has been applied to the sensor package, corresponds to a tumble test of a device comprising the sensor package, e.g., in which the device has been subject to repetitive random free-falls in a controlled manner, and/or a drop test of the device, e.g., in which the device has been dropped on its back, corner, and from 1 meter.

In yet other embodiment(s), an operating temperature range of the sensor package for which the tumble test and the drop test are performed is greater than or equal to −40 degrees Centigrade and less than or equal to 85 degrees Centigrade.

In yet other embodiment(s), the RTV material is cured, after the monolithic die has been attached to the defined area, based on a desired bond line thickness of the RTV material, e.g., approximately 25 microns (e.g., 25+/−4 microns).

In embodiment(s), the RTV material comprises a glass transition temperature that is equal to or less than negative 110 degrees Centigrade.

In various embodiment(s), the sensor package further comprises a mold compound (180), e.g., comprising a plastic material, which is formed over the monolithic die, e.g., encapsulating the monolithic die, the wires, and exposed portions of the top portion of the substrate.

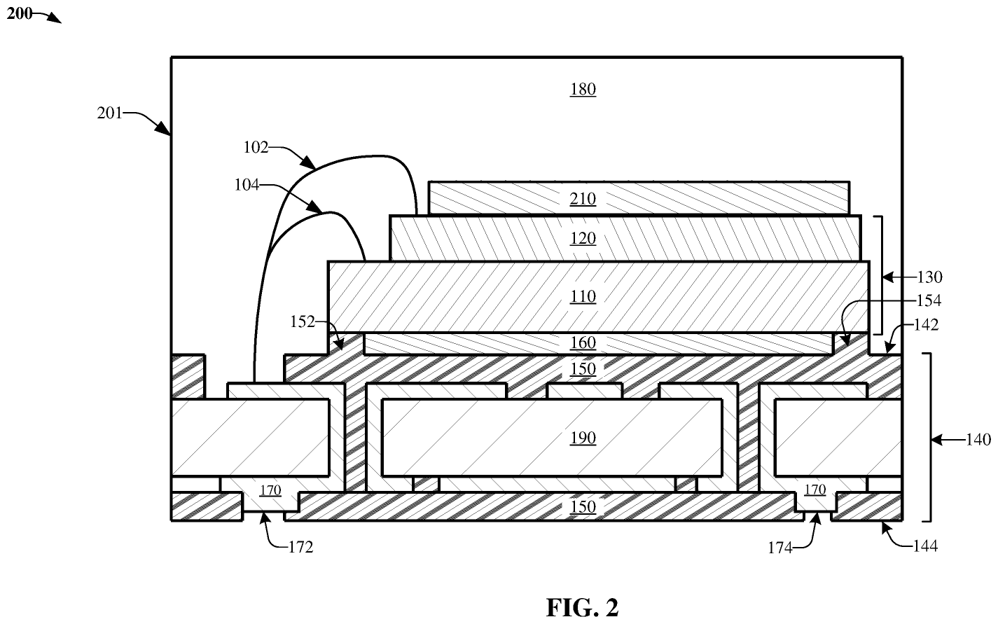

FIG. 2 illustrates a diagram (200) of a cross section of a sensor package (201) in which an RTV material (210) has been placed on a monolithic die (130) comprising a group of dies (110, 120) to facilitate improvement of a performance of the sensor package, in accordance with various example embodiments. In this regard, the RTV material facilitates absorbing and/or isolating an external stress, e.g., caused by external temperature(s) and/or external force(s), that has been applied to the sensor package to facilitate improvement of a performance of a motion sensor (not shown), e.g., a MEMS-based sensor/device that has been included in the monolithic die.

In other embodiment(s), a robustness of the sensor package, e.g., with respect to being subject to the external stress that has been applied to the sensor package, corresponds to a tumble test of a device comprising the sensor package, e.g., in which the device has been subject to repetitive random free-falls in a controlled manner, and/or a drop test of the device, e.g., in which the device has been dropped on its back, corner, and from 1 meter.

In yet other embodiment(s), an operating temperature range of the sensor package for which the tumble test and the drop test are performed is greater than or equal to −40 degrees Centigrade and less than or equal to 85 degrees Centigrade.

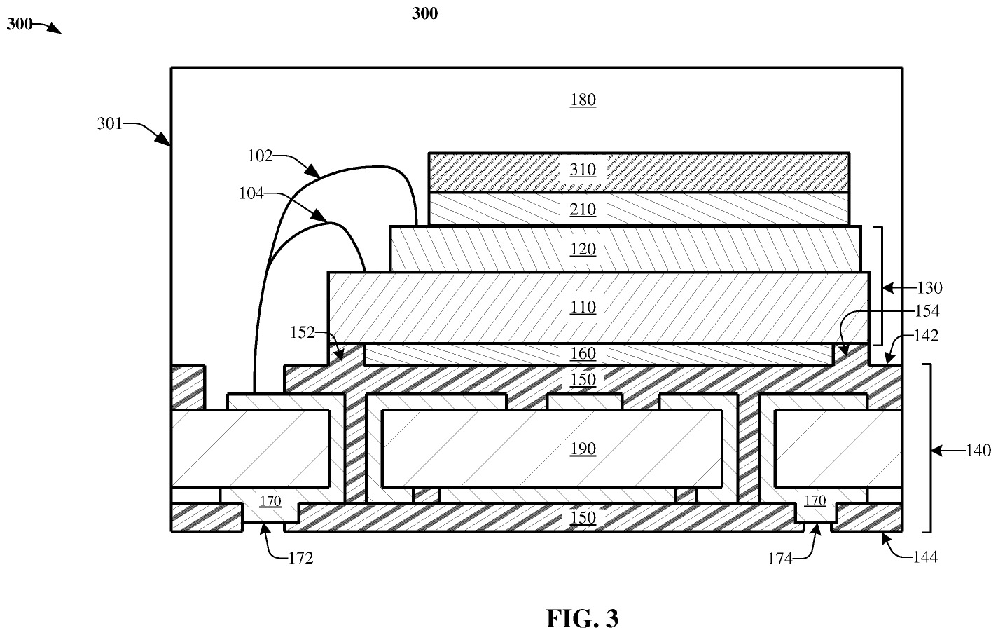

FIG. 3 illustrates a diagram (300) of a cross section of a sensor package (301) in which an RTV material (210) has been used to secure a die (310) to a monolithic die (130) comprising a group of dies (110, 120) to facilitate improvement of a performance of the sensor package, in accordance with various example embodiments. In this regard, the RTV material facilitates absorbing and/or isolating an external stress, e.g., caused by external temperature(s) and/or external force(s), that has been applied to the sensor package to facilitate improvement of a performance of a motion sensor (not shown), e.g., a MEMS-based sensor/device that has been included in the die (310) or the monolithic die (130).

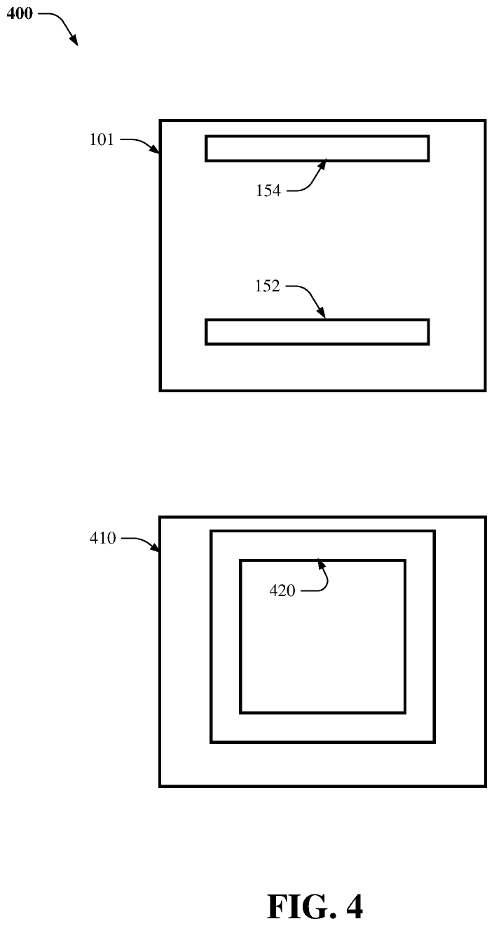

FIG. 4 illustrates a diagram (400) of respective top views of substrates of sensor packages (101, 410)—the substrates comprising a pair of solder resist dams (152, 154) that are arranged in a two-column pattern, and a plurality of solder resist dams (420) that are arranged in a rectangular pattern, respectively, in accordance with various example embodiments.

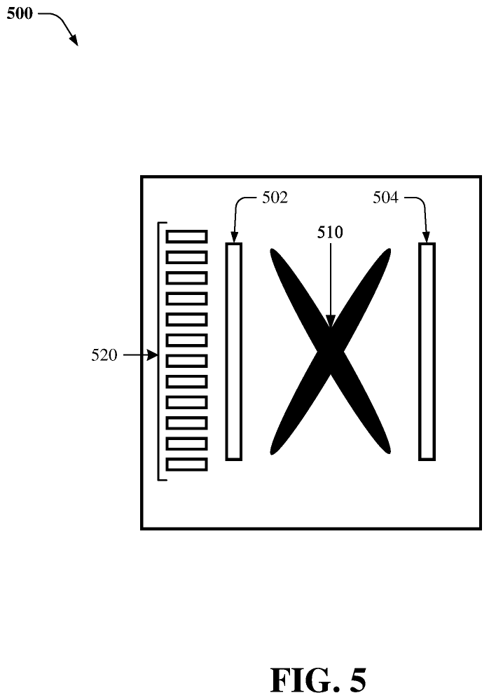

FIG. 5 illustrates a diagram (500) of a top view of a substrate, e.g., a PCB, comprising a pair of solder resist dams (502, 504) that are arranged in a two-column pattern. In this regard, an RTV material (510) is dispensed, e.g., in a crossing pattern, between the pair of solder resist dams to facilitate attachment, between the pair of solder resist dams, of a die (e.g., 110, 130) to the substrate, in accordance with various example embodiments. As illustrated by FIG. 5, the substrate further comprises bond pads (520) that facilitate electrical coupling, e.g., via wires or electrical terminals, of the die to the substrate.

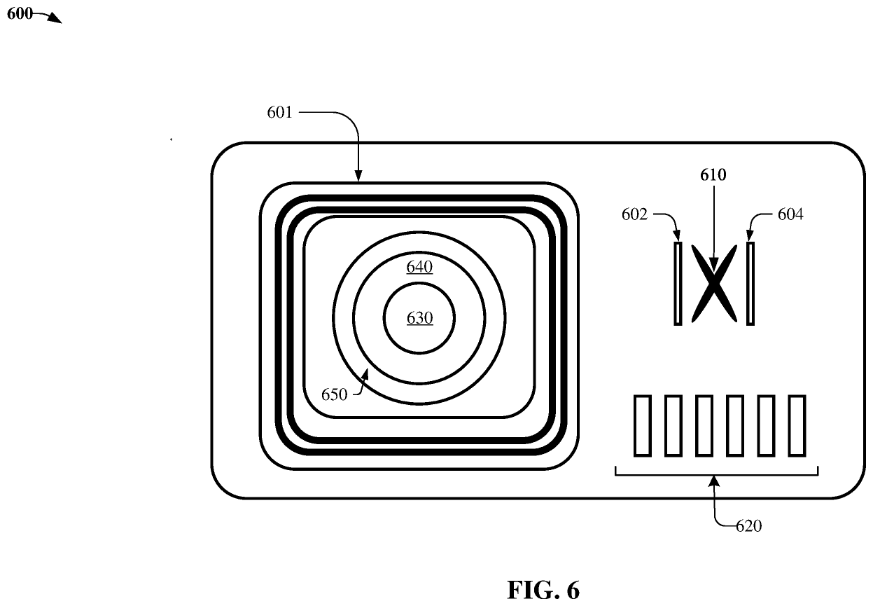

FIG. 6 illustrates a diagram (600) of a top view of a substrate, e.g., a PCB, comprising a MEMS-based microphone (601), a pair of solder resist dams (602, 604) that are arranged in a two-column pattern, and an RTV material (610) that is dispensed, e.g., in a crossing pattern, between the pair of solder resist dams to facilitate attachment of a die (e.g., 110, 130) between the pair of solder resist dams, in accordance with various example embodiments. As illustrated by FIG. 6, the substrate further comprises bond pads (620) that facilitate electrical coupling, e.g., via wires or electrical terminals, of the die to the substrate.

The MEMS-based microphone comprises a sound port (630), a solder resist dam (640) surrounding the sound port, and an RTV material (650) that has been placed on the substrate to facilitate attachment of the microphone to the substrate. As illustrated by FIG. 6, the RTV material has been disposed around a boundary of an outside portion of the solder resist dam during a defined viscous state of the RTV material, e.g., the boundary comprising a defined area located outside of the solder resist dam, in which the sound port is located adjacent to an inside portion of the solder resist dam.

In various embodiment(s), the solder resist dam prevents the RTV material from flowing, during the defined viscous state, into the sound port of the microphone.

In embodiment(s), the RTV material is cured, after the microphone has been attached to the substrate during the defined viscous state, based on a defined applied heat that has been applied to the substrate, and based on a defined applied temperature that has been applied to the substrate, to obtain a defined solid state of the RTV material—the defined solid state of the RTV material comprising a defined elasticity, e.g., that facilitates absorption and/or isolation of an external stress, e.g., caused by external temperature(s) and/or external force(s), that has been applied to the substrate.

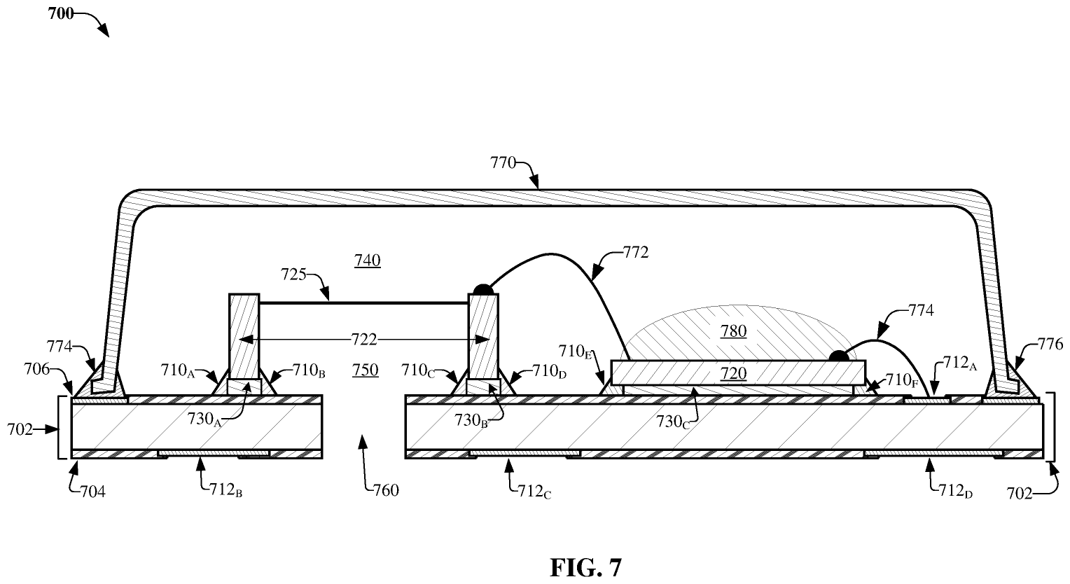

FIG. 7 illustrates a diagram (700) of a cross section of a sensor package in which an RTV material (730_{A}, 730_{B}, 730_{C}) has been used to secure respective dies (720, 722) to a substrate (702) to facilitate improvement of a performance of the sensor package, in accordance with various example embodiments. The substrate comprises a top portion (706) and a bottom portion (704). The top portion comprises a plurality of solder resist dams (710_{A}, 710_{B}, 710_{C}, 710_{D}, 710_{E}, 710_{F}) and at least one bond pad opening (712_{A}). Respective electrical terminals, e.g., 712_{B}, a ground (GND) ring (e.g., 712_{C}), a land grid array (LGA) pad (e.g., 712_{D}), electrically couple, via via(s) (not shown) and/or wire(s) (e.g., 774), die(s) (e.g., 720) to a PCB (not shown).

A first semiconductor die (720) is attached to the substrate via an RTV material (730_{C}). A second semiconductor die (722) is attached to the substrate via the RTV material (730_{A}, 730_{B}), and the plurality of solder resist dams prevent the RTV from contacting the bond pad opening(s). The second semiconductor die comprises a MEMS microphone comprising a membrane (725). One side of the membrane is adjacent to a back volume (740) of the MEMS microphone, and another side of the membrane is adjacent to a front volume (750) of the MEMS microphone that corresponds to a through hole (760), e.g., sound hole, of the MEMS microphone.

The MEMS microphone is electronically coupled to the first semiconductor die via wire 772, and a lid (770) is attached to the substrate via solder (774, 776). A “glob top” (780) comprising an encapsulant material is placed over the first semiconductor die and portion(s) of wires electrically connected to the first semiconductor die.

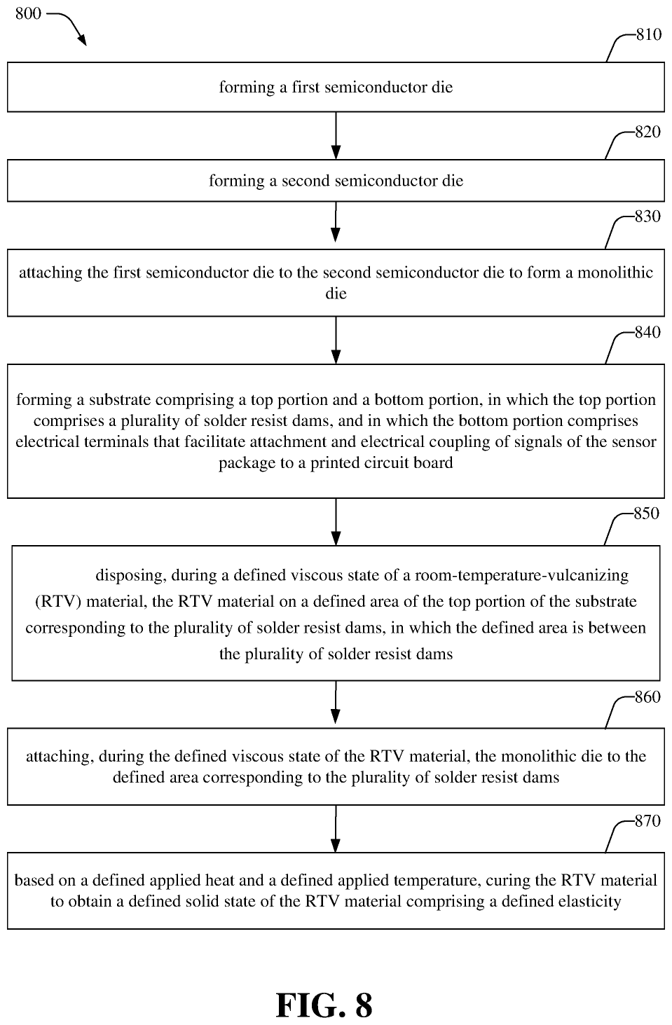

Now referring to FIG. 8, a method of manufacturing a sensor package (e.g., 101, 201, 301) is illustrated, in accordance with various example embodiments. At 810, a first semiconductor die is formed. At 820, a second semiconductor die is formed. At 830, the first semiconductor die is attached to the second semiconductor die to form a monolithic die.

At 840, a substrate is formed—the substrate comprising a top portion and a bottom portion, in which the top portion comprises a plurality of solder resist dams, and in which the bottom portion comprises electrical terminals that facilitate attachment and electrical coupling of signals of the sensor package to a PCB.

In embodiment(s), the forming of the substrate further comprises forming the solder resist dams in a 2-column pattern, in which the solder resist dams are formed across from each other.

In other embodiment(s), the forming of the substrate further comprises forming the solder resist dams in a rectangular pattern.

At 850, an RTV material is disposed, during a defined viscous state of the RTV material, on a defined area of the top portion of the substrate corresponding to the plurality of solder resist dams, in which the defined area is located between the plurality of solder resist dams.

At 860, the monolithic die is attached, during the defined viscous state of the RTV material, to the defined area corresponding to the plurality of solder resist dams.

At 870, based on a defined applied heat and a defined applied temperature, the RTV material is cured to obtain a defined solid state of the RTV material comprising a defined elasticity.

In embodiment(s), the curing of the RTV material comprises curing the RTV material based on a desired bond line thickness of the RTV material.

The above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

What is claimed is:

1. A sensor package, comprising:
a first semiconductor die;
a second semiconductor die that is attached to the first semiconductor die to form a monolithic die; and
a substrate comprising a top portion and a bottom portion, wherein the top portion comprises a plurality of solder resist dams, wherein the monolithic die is attached to the top portion of the substrate via a room-temperature-vulcanizing (RTV) material that is disposed in a defined area of the top portion of the substrate, and wherein the bottom portion of the substrate comprises electrical terminals that facilitate attachment and electrical coupling of signals of the sensor package to a printed circuit board.

2. The sensor package of claim 1, wherein the first semiconductor die or the second semiconductor die comprises redistribution layer circuitry or complementary metal-oxide-semiconductor circuitry.

3. The sensor package of claim 1, wherein the first semiconductor die or the second semiconductor die comprises a micro-electromechanical systems device.

4. The sensor package of claim 1, further comprising:
a third semiconductor die that is attached to the monolithic die.

5. The sensor package of claim 1, further comprising:
a third semiconductor die that is disposed on the top portion of the substrate.

6. The sensor package of claim 1, wherein a boundary of the defined area comprises the plurality of solder resist dams.

7. The sensor package of claim 1, wherein the RTV material is cured, after the monolithic die has been attached to the defined area, based on a defined applied heat and a defined applied temperature to obtain a defined solid state of the RTV material comprising a defined elasticity.

8. The sensor package of claim 7, wherein the RTV material is cured, after the monolithic die has been attached to the defined area, based on a desired bond line thickness of the RTV material.

9. The sensor package of claim 7, wherein the plurality of solder resist dams prevents the RTV material from flowing beyond the plurality of solder resist dams during a defined viscous state of the RTV material representing a defined viscosity of the RTV material.

10. The sensor package of claim 1, the wherein the plurality of solder resist dams comprises a pair of solder resist dams that are arranged in a two-column pattern, and wherein the monolithic die is attached between the pair of solder resist dams.

11. The sensor package of claim 1, wherein the plurality of solder resist dams is arranged in a rectangular pattern, and wherein the monolithic die is attached within the rectangular pattern.

12. The sensor package of claim 1, wherein the plurality of solder resist dams comprises a defined height from the top portion of the substrate.

13. The sensor package of claim 1, wherein a robustness of the sensor package corresponds to at least one of a tumble test of the sensor package or a drop test of the sensor package.

14. The sensor package of claim 1, wherein the RTV material comprises a glass transition temperature that is equal to or less than negative 110 degrees Centigrade.

15. The sensor package of claim 14, wherein an operating temperature range of the sensor package for which the tumble test and the drop test are performed is greater than or equal to −40 degrees Centigrade and less than or equal to 85 degrees Centigrade.

16. The sensor package of claim 1, further comprising:
a mold compound that is formed over the monolithic die.

17. A method of manufacturing a sensor package, comprising:
forming a first semiconductor die;
forming a second semiconductor die;
attaching the first semiconductor die to the second semiconductor die to form a monolithic die;
forming a substrate comprising a top portion and a bottom portion, wherein the top portion comprises a plurality of solder resist dams, and wherein the bottom portion comprises electrical terminals that facilitate attachment and electrical coupling of signals of the sensor package to a printed circuit board;
disposing, during a defined viscous state of a room-temperature-vulcanizing (RTV) material, the RTV material on a defined area of the top portion of the substrate corresponding to the plurality of solder resist dams, wherein the defined area is located between the plurality of solder resist dams;
attaching, during the defined viscous state of the RTV material, the monolithic die to the defined area corresponding to the plurality of solder resist dams; and
based on a defined applied heat and a defined applied temperature, curing the RTV material to obtain a defined solid state of the RTV material comprising a defined elasticity.

18. The method of manufacturing the sensor package of claim 17, wherein the forming of the substrate further comprises:
forming the solder resist dams in a 2-column pattern in which the solder resist dams are formed across from each other.

19. The method of manufacturing the sensor package of claim 17, wherein the forming of the substrate further comprises:
forming the solder resist dams in a rectangular pattern.

20. The method of manufacturing the sensor package of claim 17, wherein the curing of the RTV material comprises:
curing the RTV material based on a desired bond line thickness of the RTV material.

21. A sensor package, comprising:
a substrate comprising a top portion and a bottom portion, wherein the top portion comprises a plurality of solder resist dams and at least one bond pad opening;
a first semiconductor die that is attached to the substrate via a room-temperature-vulcanizing (RTV) material; and
a second semiconductor die that is attached to the substrate via the RTV material, wherein the bottom portion comprises electrical terminals that facilitate attachment and electrical coupling of signals of the sensor package to a printed circuit board, and wherein the plurality of solder resist dams prevent the RTV from contacting the at least one bond pad opening.

22. The sensor package of claim 21, wherein the substrate comprises at least one through hole.

23. The sensor package of claim 22, wherein the second semiconductor die is disposed over the at least one through hole.

24. The sensor package of claim 21, further comprising:
a lid that is attached to the substrate.
